(19) United States
(12) Patent Application Publication
(10) Pub. No.: US 2026/0262297 A1
(43) Pub. Date: Sep. 3, 2026

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Kyungpil NAM, Himeji Hyogo (JP); Shunsuke ASABA, Himeji Hyogo (JP); Hiroshi KONO, Himeji Hyogo (JP); Yujiro HARA, Himeji Hyogo (JP)

(21) Appl. No.: 19/264,090

(22) Filed: Jul. 9, 2025

(30) Foreign Application Priority Data
Feb. 28, 2025 (JP) 2025-031926

(51) Int. Cl. H10D 89/60; H10D 84/00

(52) U.S. Cl. CPC H10D 89/611; H10D 84/146

(57) ABSTRACT

According to one embodiment, a semiconductor device includes first to third electrodes, a semiconductor member, and a first insulating member. The third electrode extends along a second direction crossing a first direction from the first electrode to the second electrode. The first insulating member includes a first insulating region. The semiconductor member includes a diode portion and a transistor portion. In the transistor portion, the third partial region is between the first partial region and the third electrode in the first direction. In the diode portion, a part of the second semiconductor region is provided between the first partial region and the third electrode. The diode portion includes a first diode region. The transistor portion includes a first transistor region. A direction from the first diode region to the first transistor region is along the second direction.

### CROSS-REFERENCE TO RELATED APPLICATIONS

This application is based upon and claims the benefit of priority from Japanese Patent Application No.2025-031926, filed on Feb. 28, 2025; the entire contents of which are incorporated herein by reference.

### FIELD

Embodiments described herein relate generally to a semiconductor device.

### BACKGROUND

For example, in semiconductor devices, improvements in characteristics are desired.

### BRIEF DESCRIPTION OF THE DRAWINGS

FIG. 1 is a schematic plan view illustrating a semiconductor device according to a first embodiment;

FIG. 2 is a schematic cross-sectional view illustrating a part of the semiconductor device according to the first embodiment;

FIG. 3 is a schematic cross-sectional view illustrating a part of the semiconductor device according to the first embodiment;

FIG. 4 is a schematic perspective view illustrating a part of the semiconductor device according to the first embodiment; and

FIG. 5 is a schematic plan view illustrating a part of the semiconductor device according to the first embodiment.

### DETAILED DESCRIPTION

According to one embodiment, a semiconductor device includes a first electrode, a second electrode, a third electrode, a semiconductor member, and a first insulating member. The semiconductor member is provided between the first electrode and the second electrode. The third electrode extends along a second direction crossing a first direction from the first electrode to the second electrode. The first insulating member includes a first insulating region. The first insulating region is between the semiconductor member and the third electrode. The semiconductor member includes a first semiconductor region of a first conductivity type, a second semiconductor region of a second conductivity type, and a third semiconductor region of the first conductivity type. The first semiconductor region includes a first partial region, a second partial region, and a third partial region. A third direction from the first partial region to the second partial region crosses a plane including the first direction and the second direction. The second partial region is between the first electrode and the second semiconductor region in the first direction. At least a part of the third semiconductor region is between the second semiconductor region and the second electrode. The third semiconductor region is electrically connected to the second electrode. The semiconductor member includes a diode portion and a transistor portion. In the transistor portion, the third partial region is between the first partial region and the third electrode in the first direction. In the transistor portion, a direction from the third partial region to the second semiconductor region is along the third direction. In the diode portion, the third partial region is not provided between the first partial region and the third electrode. In the diode portion, a part of the second semiconductor region is provided between the first partial region and the third electrode. The diode portion includes a first diode region. The transistor portion includes a first transistor region. A direction from the first diode region to the first transistor region is along the second direction.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### FIRST EMBODIMENT

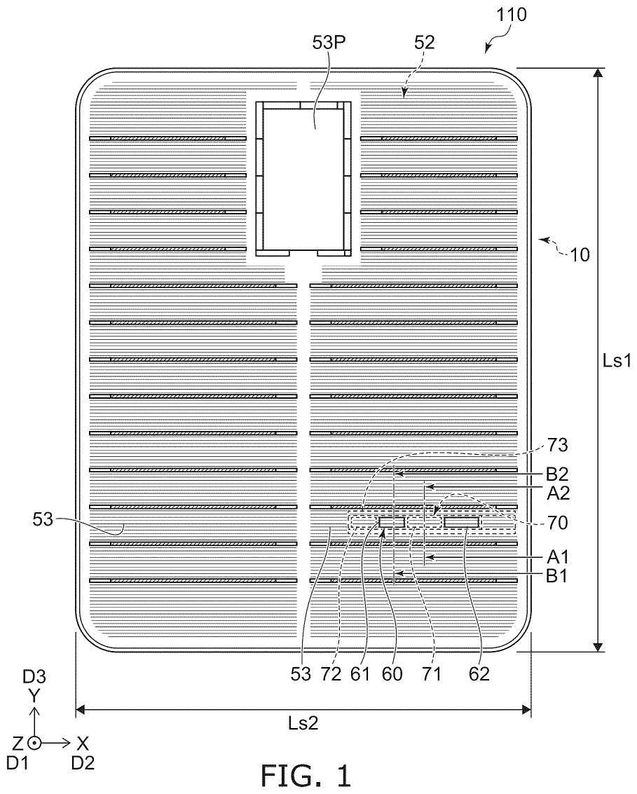

FIG. 1 is a schematic plan view illustrating a semiconductor device according to a first embodiment.

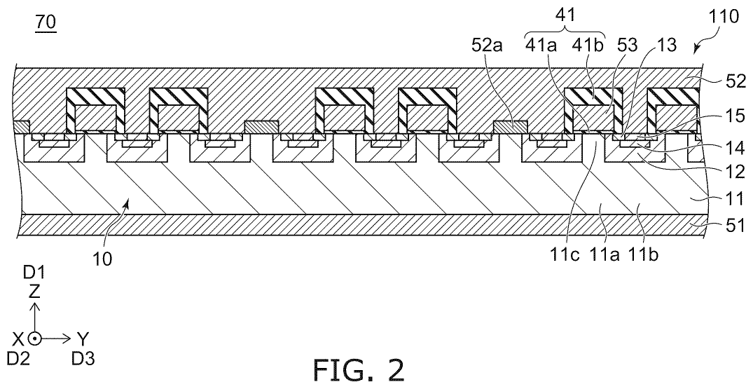

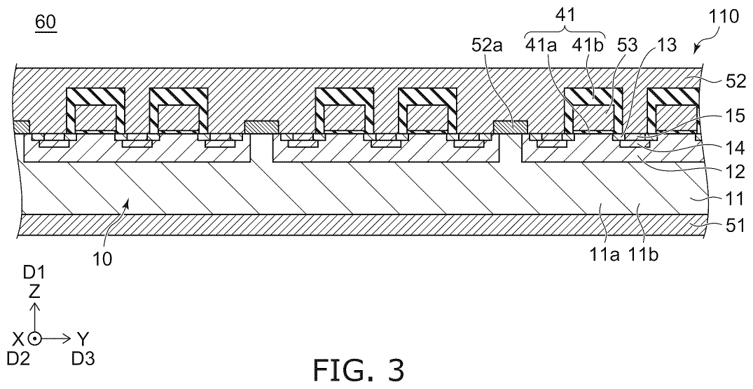

FIGS. 2 and 3 are schematic cross-sectional views illustrating a part of the semiconductor device according to the first embodiment.

FIG. 2 is a cross-sectional view taken along the line A1-A2 in FIG. 1. FIG. 3 is a cross-sectional view taken along the line B1-B2 in FIG. 1.

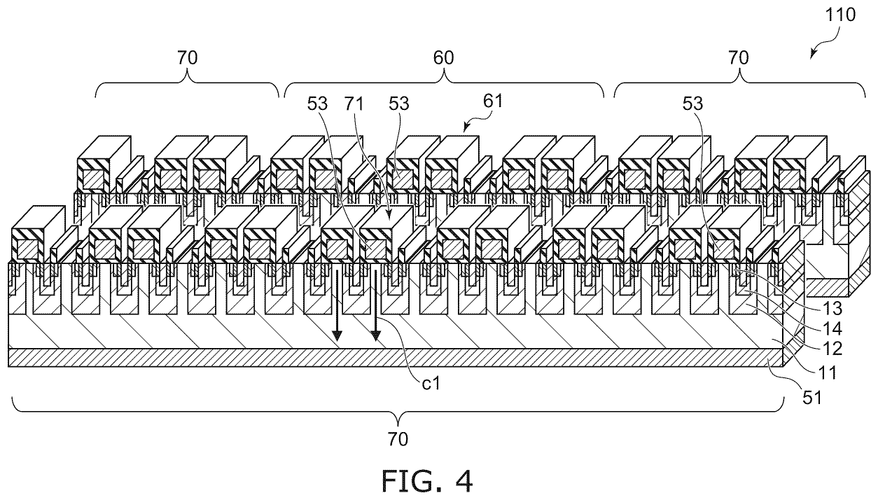

FIG. 4 is a schematic perspective view illustrating a part of the semiconductor device according to the first embodiment.

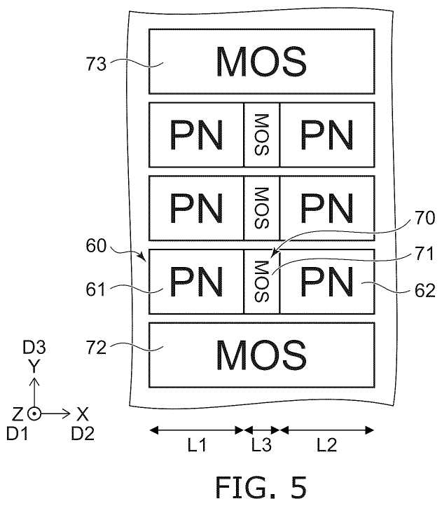

FIG. 5 is a schematic plan view illustrating a part of the semiconductor device according to the first embodiment.

As shown in FIGS. 1 to 4, ae semiconductor device 110 according to the embodiment includes a first electrode 51, a second electrode 52, a third electrode 53, a semiconductor member 10, and a first insulating member 41.

The semiconductor member 10 is provided between the first electrode 51 and the second electrode 52. A first direction D1 from the first electrode 51 to the second electrode 52 is defined as a Z-axis direction. A direction perpendicular to the Z-axis direction is defined as an X-axis direction. A direction perpendicular to the Z-axis direction and the X-axis direction is defined as a Y-axis direction.

The third electrode 53 extends along the second direction D2. The second direction D2 crosses the first direction D1 from the first electrode 51 to the second electrode 52. The second direction D2 may be, for example, the X-axis direction.

As shown in FIG. 2, the first insulating member 41 includes a first insulating region 41a. The first insulating region 41a is between the semiconductor member 10 and the third electrode 53. The first insulating member 41 may further include a second insulating region 41b. At least a part of the second insulating region 41b is between the third electrode 53 and the second electrode 52.

As shown in FIG. 2, the semiconductor member 10 includes a first semiconductor region 11 of a first conductivity type, a second semiconductor region 12 of a second conductivity type, and a third semiconductor region 13 of the first conductivity type. The first conductivity type is one of n-type and p-type. The second conductivity type is the other of n-type and p-type. In the following, the first conductivity type is n-type and the second conductivity type is p-type.

The first semiconductor region 11 includes a first partial region 11a, a second partial region 11b, and a third partial region 11c. A third direction D3 from the first partial region 11a to the second partial region 11b crosses a plane (e.g., a Z-X plane) including the first direction D1 and the second direction D2. The third direction D3 may be, for example, the Y-axis direction.

The second partial region 11b is between the first electrode 51 and the second semiconductor region 12 in the first direction D1. At least a part of the third semiconductor region 13 is between the second semiconductor region 12 and the second electrode 52. The third semiconductor region 13 is electrically connected to the second electrode 52.

As shown in FIG. 1, the semiconductor member 10 includes a diode portion 60 and a transistor portion 70. FIG. 2 illustrates a cross section of the transistor portion 70. FIG. 3 illustrates a cross section of the diode portion 60.

As shown in FIG. 2, in the transistor portion 70, the third partial region 11c is between the first partial region 11a and the third electrode 53 in the first direction D1. In the transistor portion 70, a direction from the third partial region 11c to the second semiconductor region 12 is along the third direction D3.

As shown in FIG. 3, in the diode portion 60, the third partial region 11c is not provided between the first partial region 11a and the third electrode 53. In the diode portion 60, a part of the second semiconductor region 12 is provided between the first partial region 11a and the third electrode 53. For example, a PN diode is formed by the second semiconductor region 12 and the first semiconductor region 11.

As shown in FIG. 1, the diode portion 60 includes a first diode region 61. The transistor portion 70 includes a first transistor region 71. A direction from the first diode region 61 to the first transistor region 71 is along the second direction D2.

Current flowing between the first electrode 51 and the second electrode 52 can be controlled by a potential of the third electrode 53. The potential of the third electrode 53 may be, for example, a potential based on a potential of the second electrode 52. The first electrode 51 functions, for example, as a drain electrode. The second electrode 52 functions, for example, as a source electrode. The third electrode 53 functions, for example, as a gate electrode. The semiconductor device 110 is, for example, a transistor. The transistor portion 70 is, for example, a MOS (Metal Oxide Semiconductor) region.

In the embodiment, by providing the diode portion 60, for example, adverse effects due to surge currents are suppressed. For example, destruction caused by surge currents is suppressed.

As shown in FIG. 4, in the embodiment, the direction from the first diode region 61 to the first transistor region 71 is along the second direction D2 (see FIG. 1). The first transistor region 71 is provided next to the first diode region 61. In ON-operation, the carriers c1 flowing through the first diode region 61 can flow toward the first electrode 51 via the first transistor region 71. Thereby, a decrease in the current in ON-state caused by the diode portion 60 (for example, the first diode region 61) is suppressed. The first transistor region 71 becomes a current path. In the embodiment, a low ON-resistance is obtained. According to the embodiment, a semiconductor device with improved characteristics can be provided.

For example, an area of the PN region of the diode portion 60 per unit area is larger than an area of the PN region of the transistor portion 70 per unit area. The current flowing through the PN junction diode included in the diode portion 60 is larger than the current flowing through the PN junction diode included in the transistor portion 70.

A resistance of the diode portion 60 is lower than a resistance of the diode (body diode) included in the transistor portion 70 (MOSFET portion). For example, when a large current such as a surge is applied, the current flows preferentially through the diode portion 60. For example, the diode portion 60 has the effect of concentrating the surge current.

When a surge current is applied, the diode portion 60 is more likely to lead to conductivity modulation than the MOSFET portion, and the effect of conductivity modulation is also stronger. For example, this region where the conductivity is modulated becomes the “starting point.” Carriers generated based on the conductivity modulation spread to the neighboring cell, and the amount of current further increases. When the amount of current increases, heat is generated in the diode portion 60, and the forward voltage Vf of the diode portion 60 decreases. This provides positive feedback. The surge current is concentrated in the diode portion 60. The diode portion 60 becomes the starting point of the conductivity modulation. For example, the large current and heat can be dispersed to the neighboring diode portion 60.

As shown in FIGS. 1 and 5, the diode portion 60 may further include a second diode region 62. The first transistor region 71 is between the first diode region 61 and the second diode region 62 in the second direction D2.

As shown in FIGS. 1 and 5, the transistor portion 70 may further include a second transistor region 72. A direction from at least a part of the second transistor region 72 to the first diode region 61 is along the third direction D3.

The transistor portion 70 may further include a third transistor region 73. The first diode region 61 is between the second transistor region 72 and the third transistor region 73 in the third direction D3. The second diode region 62 is between the second transistor region 72 and the third transistor region 73 in the third direction D3.

In this manner, the transistor portion 70 may be provided next to each of the first diode region 61 and the second diode region 62. A low ON-resistance is obtained by the transistor portion 70 functioning as a current path.

For example, as described above, by providing the first transistor region 71 between the first diode region 61 and the second diode region 62, for example, a low ON-resistance can be obtained. The diode region suppresses the adverse effects of surge current. On the other hand, since the diode region does not operate in the ON-operation, it is possible that the ON-resistance may deteriorate. At this time, the first transistor region 71 functions as a bypass region for the current, thereby mitigating the deterioration of the ON-resistance. As a result, a low ON-resistance can be obtained.

As shown in FIG. 5, a plurality of first diode regions 61 and a plurality of second diode regions 62 may be provided between the second transistor region 72 and the third transistor region 73. The first transistor region 71 may be provided between one of the plurality of first diode regions 61 and one of the plurality of second diode regions 62.

In one example, the first length L1 in the second direction D2 of the first diode region 61 may be longer than the third length L3 in the second direction D2 of the first transistor region 71. In one example, the second length L2 in the second direction D2 of the second diode region 62 may be longer than the third length L3 in the second direction D2 of the first transistor region 71.

In one example. The first length L1 may be not less than 1 time and not more than 10 times the third length L3. The first length L1 may be not less than 4 times and not more than 6 times the third length L3. The second length L2 may be not less than 1 time and more than 10 times the third length L3. The second length L2 may be not less than 4 times and not more than 6 times the third length L3. In one example, the third length L3 may be not less than 5μm and not more than 30μm.

The length (width) of the first diode region 61 in the first direction D1 may be not less than 0.9 times and not more than 1.1 times the length (width) of the first transistor region 71 in the first direction D1. The length (width) of the first transistor region 71 in the first direction D1 may be, for example, not less than 5μm and not more than 30μm.

As shown in FIG. 1, for example, the length Ls1 along the third direction D3 of the semiconductor member 10 may not less than the length Ls2 along the second direction D2 of the semiconductor member 10.

As shown in FIGS. 1 to 3, a plurality of third electrodes 53 may be provided. The plurality of third electrodes 53 are arranged along the third direction D3. As shown in FIGS. 2 and 3, the diode portion 60 and the transistor portion 70 are provided corresponding to the plurality of third electrodes 53.

In the embodiment, a third impurity concentration of the first conductivity type in the third semiconductor region 13 is higher than a first impurity concentration of the first conductivity type in the first semiconductor region 11.

As shown in FIGS. 2 and 3, the semiconductor member 10 may further include a fourth semiconductor region 14 of the second conductivity type. The fourth semiconductor region 14 is between the second semiconductor region 12 and the second electrode 52. The fourth impurity concentration of the second conductivity type in the fourth semiconductor region 14 is higher than the second impurity concentration of the second conductivity type in the second semiconductor region 12.

As shown in FIGS. 2 and 3, the semiconductor member 10 may further include a fifth semiconductor region 15 of the second conductivity type. The fifth semiconductor region 15 is between the fourth semiconductor region 14 and the second electrode 52. A fifth impurity concentration of the second conductivity type in the fifth semiconductor region 15 is higher than the fourth impurity concentration.

As shown in FIGS. 2 and 3, the semiconductor device 110 may further include a first electrode portion 52a. The first electrode portion 52a is between the first semiconductor region 11 and the second electrode 52. For example, a Schottky diode may be formed in the portion including the first electrode portion 52a. The first electrode portion 52a may include, for example, at least one selected from the group consisting of Ti and Al.

As shown in FIGS. 2 and 3, a position of the first electrode portion 52a along the third direction D3 is between a position of one of the plurality of third electrodes 53 in the third direction D3 and a position of another of the plurality of third electrodes 53 in the third direction D3.

The semiconductor member 10 may include SiC or Si. The semiconductor member 10 may include, for example, at least one selected from the group consisting of 4H-SiC, 6H-SiC, and 3C-SiC. When the semiconductor member 10 includes SiC, the first conductivity type impurity includes, for example, at least one selected from the group consisting of N, P, and As. When the semiconductor member 10 includes SiC, the second conductivity type impurity includes, for example, at least one selected from the group consisting of B, Al, and Ga. The semiconductor member 10 may include, for example, a compound semiconductor including Ga.

At least one of the first electrode 51 and the second electrode 52 may include at least one selected from the group consisting of Al, Cu, Ti, Ni, Ag, and Au. At least one of the first electrode 51 and the second electrode 52 may include at least one selected from the group consisting of titanium silicide and nickel silicide. The third electrode 53 may include, for example, conductive polysilicon.

In the embodiment, information regarding length and thickness is obtained by observation using an electron microscope, etc. Information regarding the composition of the material is obtained by SIMS (Secondary Ion Mass Spectrometry) or EDX (Energy dispersive X-ray spectroscopy), etc.

According to the embodiment, a semiconductor device with improved characteristics can be provided.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in semiconductor devices such as electrodes, semiconductor members, insulating members, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a first electrode;
a second electrode;
a semiconductor member provided between the first electrode and the second electrode;
a third electrode extending along a second direction crossing a first direction from the first electrode to the second electrode; and
a first insulating member including a first insulating region, the first insulating region being between the semiconductor member and the third electrode,
the semiconductor member including:
a first semiconductor region of a first conductivity type;
a second semiconductor region of a second conductivity type; and
a third semiconductor region of the first conductivity type,
the first semiconductor region including a first partial region, a second partial region, and a third partial region,
a third direction from the first partial region to the second partial region crossing a plane including the first direction and the second direction,
the second partial region being between the first electrode and the second semiconductor region in the first direction,
at least a part of the third semiconductor region being between the second semiconductor region and the second electrode,
the third semiconductor region being electrically connected to the second electrode,
the semiconductor member including a diode portion and a transistor portion,
in the transistor portion, the third partial region being between the first partial region and the third electrode in the first direction,
in the transistor portion, a direction from the third partial region to the second semiconductor region being along the third direction,
in the diode portion, the third partial region being not provided between the first partial region and the third electrode,
in the diode portion, a part of the second semiconductor region being provided between the first partial region and the third electrode,
the diode portion including a first diode region,
the transistor portion including a first transistor region, and
a direction from the first diode region to the first transistor region being along the second direction.

2. The semiconductor device according to claim 1, wherein
the diode portion further includes a second diode region, and
the first transistor region is between the first diode region and the second diode region in the second direction.

3. The semiconductor device according to claim 2, wherein
the transistor portion further includes a second transistor region, and
a direction from at least a part of the second transistor region to the first diode region is along the third direction.

4. The semiconductor device according to claim 3, wherein
the transistor portion further includes a third transistor region, and
the first diode region is between the second transistor region and the third transistor region in the third direction.

5. The semiconductor device according to claim 4, wherein
the second diode region is between the second transistor region and the third transistor region in the third direction.

6. The semiconductor device according to claim 4, wherein
a plurality of the first diode regions and a plurality of the second diode regions are provided between the second transistor region and the third transistor region.

7. The semiconductor device according to claim 1, wherein
a plurality of the third electrodes are provided,
the plurality of the third electrodes are arranged along the third direction, and
the diode portion and the transistor portion are provided corresponding to the plurality of the third electrodes.

8. The semiconductor device according to claim 1, wherein
a first length of the first diode region in the second direction is longer than a third length of the first transistor region in the second direction.

9. The semiconductor device according to claim 8, wherein
the first length is not less than 1 time and not more than 10 times the third length.

10. The semiconductor device according to claim 2, wherein
each of a first length in the second direction of the first diode region and a second length in the second direction of the second diode region are longer than a third length in the second direction of the first transistor region.

11. The semiconductor device according to claim 10, wherein
the first length is not less than 1 time and not more than 10 times the third length, and
the second length is not less than 1 time and not more than 10 times the third length.

12. The semiconductor device according to claim 1, wherein
a third impurity concentration of the first conductivity type in the third semiconductor region is higher than a first impurity concentration of the first conductivity type in the first semiconductor region.

13. The semiconductor device according to claim 1, wherein
the semiconductor member further includes a fourth semiconductor region of the second conductivity type,
the fourth semiconductor region is between the second semiconductor region and the second electrode, and
a fourth impurity concentration of the second conductivity type in the fourth semiconductor region is higher than a second impurity concentration of the second conductivity type in the second semiconductor region.

14. The semiconductor device according to claim 13, wherein
the semiconductor member further includes a fifth semiconductor region of the second conductivity type,
the fifth semiconductor region is between the fourth semiconductor region and the second electrode, and
a fifth impurity concentration of the second conductivity type in the fifth semiconductor region is higher than the fourth impurity concentration.

15. The semiconductor device according to claim 1, wherein the semiconductor member includes SiC or Si.

16. The semiconductor device according to claim 1, further comprising:
a first electrode portion,
the first electrode portion being between the first semiconductor region and the second electrode, and
a Schottky diode being formed in a portion including the first electrode portion.

17. The semiconductor device according to claim 1, further comprising:
a first electrode portion,
the first electrode portion being between the first semiconductor region and the second electrode, and
the first electrode portion including at least one selected from the group consisting of Ti and Al.

18. The semiconductor device according to claim 7, further comprising:
a first electrode portion,
the first electrode portion being between the first semiconductor region and the second electrode,
the first electrode portion including at least one selected from the group consisting of Ti and Al, and
a position of the first electrode portion along the third direction being between a position in the third direction of one of the plurality of third electrodes and a position in the third direction of another of the plurality of third electrodes.

19. The semiconductor device according to claim 1, wherein
the first insulating member further includes a second insulating region, and
at least a part of the second insulating region is between the third electrode and the second electrode.

20. The semiconductor device according to claim 1, wherein
a length of the semiconductor member along the third direction is equal to or more than a length of the semiconductor member along the second direction.
